(19) United States
(12) Patent Application Publication
(10) Pub. No.: US 2022/0325801 A1
(43) Pub. Date: Oct. 13, 2022

(54) CONTROL VALVE, SUBSTRATE PROCESSING APPARATUS, METHOD OF MANUFACTURING SEMICONDUCTOR DEVICE, AND RECORDING MEDIUM

(71) Applicant: Kokusai Electric Corporation, Tokyo (JP)

(72) Inventors: Mikio ONO, Toyama-shi (JP); Tomoshi TANIYAMA, Toyama-shi (JP)

(73) Assignee: Kokusai Electric Corporation, Tokyo (JP)

(21) Appl. No.: 17/847,585

(22) Filed: Jun. 23, 2022

Related U.S. Application Data
(63) Continuation of application No. PCT/JP2020/004116, filed on Feb. 4, 2020.

(51) Int. Cl. F16K 1/22; F16K 51/02; F16K 1/226; F16K 3/02; H01L 21/67

(52) U.S. Cl. CPC F16K 1/223; F16K 51/02; F16K 1/2261; F16K 3/0209; H01L 21/67017

(57) ABSTRACT

There is provided a technique that includes: a gate valve including a movable gate valve plate; and a butterfly valve that is installed at the gate valve plate, has a diameter smaller than those of valve openings configured to be opened or closed by the gate valve plate, and is configured to be capable of being fully closed, wherein the gate valve plate of the gate valve and the butterfly valve are configured to be capable of being driven independently of each other.

### CROSS-REFERENCE TO RELATED APPLICATION

This application is a Bypass Continuation application of PCT International Application No. PCT/JP2020/004116, filed on Feb. 4, 2020, the disclosure of which is incorporated herein in its entirety by reference.

### TECHNICAL FIELD

The present disclosure relates to a control valve, a substrate processing apparatus, a method of manufacturing a semiconductor device, and a recording medium.

### BACKGROUND

In a thin film-forming process in semiconductor device manufacturing, two or more types of film-forming gases may be alternately flowed onto a substrate one by one and may be reacted with atoms on the substrate to deposit a film one layer at a time. At this time, a reaction chamber pressure during film formation differs for each film-forming gas supply event, and pressure regulation thereof is mainly performed by conductance regulation function (APC (Auto Pressure Control)) of an exhaust main valve.

In recent film-forming sequences, the number of apparatuses including a high conductance exhaust system (hereinafter referred to as a “200 A exhaust system”) is increasing to improve an exhaust speed, a gas replacement efficiency, and the like.

However, in the related art, with a 200 A regulating valve, controllability was not sufficient, because there was, for example, difficulty in regulating a pressure with a minute valve opening degree.

### SUMMARY

Some embodiments of the present disclosure provide a technique of a control valve with good controllability in response to a large flow rate exhaust from a reaction chamber.

According to embodiments of the present disclosure, there is provided a technique that includes a gate valve including a movable gate valve plate; and a butterfly valve that is installed at the gate valve plate, has a diameter smaller than those of valve openings configured to be opened or closed by the gate valve plate, and is configured to be capable of being fully closed, wherein the gate valve plate of the gate valve and the butterfly valve are configured to be capable of being driven independently of each other.

### BRIEF DESCRIPTION OF DRAWINGS

The accompanying drawings, which are incorporated in and constitute a part of the specification, illustrate embodiments of the present disclosure.

FIG. 1 is a schematic view showing an overall configuration of a substrate processing apparatus according to embodiments of the present disclosure.

FIG. 2 is a front view showing an exhaust system according to embodiments of the present disclosure.

FIG. 3 is a block diagram showing an exhaust system according to embodiments of the present disclosure.

FIG. 4A is a cross-sectional view showing a closed state of a gate valve in a control valve according to embodiments of the present disclosure. FIG. 4B is a cross-sectional view showing an open state of a gate valve in a control valve according to embodiments of the present disclosure. FIG. 4C is a cross-sectional view showing a closed state of a gate valve and a fully open state of a butterfly valve in a control valve according to embodiments of the present disclosure.

FIG. 5 is a cross-sectional view showing a modification of a control valve according to embodiments of the present disclosure. It is a graph showing a decompression state in an operation of an exhaust system.

FIG. 6 is a graph showing an example of allocation of opening state by an opening stage command calculator in an operation of an exhaust system according to embodiments of the present disclosure.

FIG. 7 is a graph showing another example of allocation of opening state by an opening state command calculator in an operation of an exhaust system according to embodiments of the present disclosure.

FIG. 8 is a graph showing an example in which the example of FIG. 7 is further modified to be suitable for high-speed opening/closing.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components are not described in detail so as not to obscure aspects of the various embodiments.

Hereinafter, an example of embodiments of the present disclosure will be described with reference to the drawings. Throughout the drawings, the same or equivalent elements and parts are denoted by the same reference numerals. In addition, dimensional ratios in the drawings are exaggerated for the sake of convenience of explanation and may differ from actual ratios. Further, an upper direction of the drawing will be described as an upper side or an upper portion, and a lower direction thereof will be described as a lower side or a lower portion. In addition, the pressures described in the embodiments mean an atmospheric pressure.

### <Overall Configuration of Substrate Processing Apparatus>

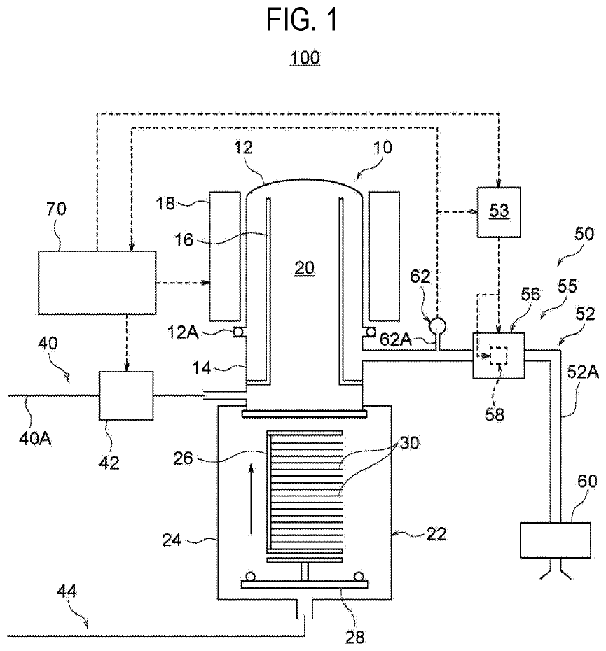

As shown in FIG. 1, a substrate processing apparatus 100 includes a reaction furnace 10 including a process chamber 20 configured to process substrates 30 as an example of semiconductor devices, a spare chamber 22 configured to store a boat 26 holding the substrates 30, a gas introduction line 40 configured to introduce a gas into the process chamber 20, an exhaust system 50 configured to discharge a gas from the process chamber 20, and a main controller 70 configured to control an operation of the substrate processing apparatus 100.

### [Reaction Furnace]

As shown in FIG. 1, the process chamber 20 including a reaction tube 12 and a furnace opening flange 14 is formed in the reaction furnace 10. The reaction tube 12 is formed in a cylindrical shape having an axis in a vertical direction. The furnace opening flange 14 is connected to a lower portion of the reaction tube 12 with an air-tight seal 12A interposed therebetween, and is formed in a cylindrical shape having an axis in the vertical direction. Further, in the reaction furnace 10, an inner tube 16 is supported inside the reaction tube 12 to be concentric with the reaction tube 12. Further, a heater 18 is installed on the outer periphery of the reaction tube 12 so as to be concentric with the axis of the reaction tube 12 and at a distance from an outer surface of the reaction tube 12. The heater 18 has a function of receiving a signal from the main controller 70, which will be described later, to generate heat and heating the reaction tube 12. In this way, the reaction furnace 10 includes the reaction tube 12, the furnace opening flange 14, the inner tube 16, the heater 18, and the process chamber 20. Further, the substrates 30 are arranged in the process chamber 20.

### [Spare Chamber]

As shown in FIG. 1, the spare chamber 22 includes a transfer housing 24. The transfer housing 24 is in fluid communication with the lower portion of the furnace opening flange 14. The boat 26 configured to mount the substrates 30, transfer and insert the substrates 30 into the process chamber 20 is stored inside the transfer housing 24. A furnace opening lid 28 is provided to be movable in the vertical direction. When the furnace opening lid 28 reaches the upper end, it air-tightly closes the transfer housing 24. The boat 26 is mounted on the furnace opening lid 28 and is introduced into the reaction furnace 10 in accordance with the movement of the furnace opening lid 28. Further, a second gas introduction line 44 of the same configuration as the gas introduction line 40 to be described later is in fluid communication with the lower portion of the transfer housing 24. As a result, an interior of the spare chamber 22 can be filled with an atmosphere in which a native oxide film and the like are unlikely to be formed on the substrates 30.

### [Gas Introduction Line]

As shown in FIG. 1, the gas introduction line 40 includes a gas introduction pipe 40A being in fluid communication with a gas supply source (not shown) with the furnace opening flange 14, and a flow rate controller 42 of the gas introduction pipe, which is provided between the gas supply source and the furnace opening flange 14. The flow rate controller 42 has a function of controlling an amount of introduction of a gas by opening/closing an internal valve (not shown) by a signal from the main controller 70 to be described later. Further, the second gas introduction line 44 has the same configuration as the gas introduction line 40 except that the second gas introduction line 44 is in fluid communication with a gas supplier with the lower portion of the transfer housing 24. The gas used here is an inert gas, specifically a nitrogen gas.

### [Main Controller]

The main controller 70 is a controller that controls the overall operation of the substrate processing apparatus 100, and although not shown, includes a computer including a CPU, a ROM, a RAM, a storage, an input part, a display, a communication interface, and the like, each of which is connected to a bus. The communication interface may acquire pressure information from a pressure sensor group 62 to be described later and transmit a target pressure value to a valve controller 53. The main controller 70 executes substrate processing programs to perform various processes in the substrate processing apparatus 100 based on input information from the input part. For example, the main controller 70 executes a process recipe, which is a substrate processing program, to control a substrate processing process which is a process of manufacturing a semiconductor device. At this time, the main controller 70 controls the opening/closing of a gate valve 56 and a butterfly valve 58 of the exhaust system 50 and regulate an opening state of the butterfly valve 58 by using the valve controller 53 to control the pressure of the process chamber 20. An opening state command calculator 72 corresponds to, for example, an APC controller.

### <Configuration of Main Components>

### [Exhaust System]

As shown in FIGS. 1 to 3, the exhaust system 50 includes a large-diameter pipe 52A as a first pipe configured to discharge a gas from the process chamber 20, a pressure sensor group 62 installed at the pipe 52A and configured to detect the pressure of the process chamber 20, and an exhaust line 52 including at least a control valve 55 installed in the middle of the pipe 52A. As shown in FIGS. 1 to 4C, the pipe 52A is a large-diameter pipe that is in fluid communication with the process chamber 20 to a vacuum pump 60, and constitutes a vacuum exhaust flow path. In the embodiments of the present disclosure, the diameter of the pipe 52A is 200 mm (200φ) as an example. That is, a nominal diameter of the pipe 52A is, for example, 200 A. A flow end portion of the exhaust line 52, which is an end portion opposite to the process chamber 20, is connected to a suction side of the vacuum pump 60. The exhaust line 52 is configured to exhaust the gas in the process chamber 20 by suction operation of the vacuum pump 60 when the control valve 55 is in an open state. The vacuum pump 60 has an ultimate vacuum degree of about 10 Pa, is always operated, and maintains a vacuum on the downstream side of the exhaust line 52. The vacuum pump 60 and the valve controller 53 may be included in the exhaust system 50.

### [Control Valve]

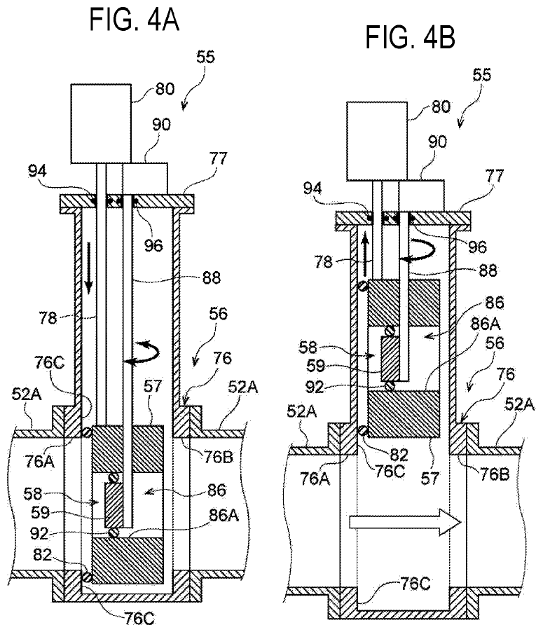

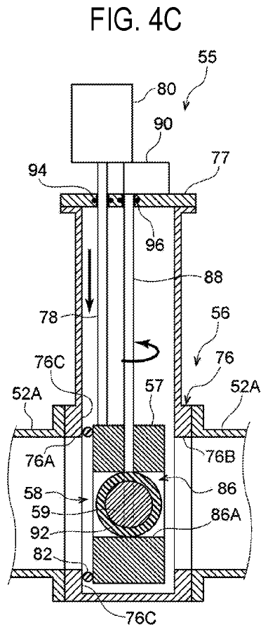

As shown in FIGS. 4A to 4C, the control valve 55 includes the gate valve 56 and the butterfly valve 58 formed in a shape of a box in the gate valve 56. A gate valve plate 57 of the gate valve 56 and the butterfly valve 58 are configured to be capable of being driven independently of each other. The gate valve 56 and the butterfly valve 58 are electrically connected to the valve controller 53 to perform an opening/closing operation based on a signal from the valve controller 53. The control valve 55 can vary a conductance of the exhaust line 52 as a vacuum exhaust flow path, and may shut off the vacuum exhaust flow path with the conductance set to be substantially 0, that is, fully closed in a variable range of the conductance.

The gate valve 56 includes a valve housing 76, a movable gate valve plate 57, a rod 78 as an example of a driver, a gate valve actuator 80, and a gate valve seal ring 82. The valve housing 76 includes two valve openings 76A and 76B arranged to face each other in the flow path direction and a gate valve seat 76C, and forms a linear flow path of fluid to be controlled between the two valve openings 76A and 76B. The fluid to be controlled is, for example, a gas used when performing the substrate processing or purging in the process chamber 20. The valve openings 76A and 76B are, for example, circular openings with flanges installed to be concentric with a center of the flow path and opposite to each other, and the flanges are formed to be connectable to the pipe 52A with the nominal diameter of 200 A. Further, inner diameters of the valve openings 76A and 76B correspond to an inner diameter of the pipe 52A with the nominal diameter of 200 A, for example. The size of the valve housing 76 is set such that the gate valve plate 57 may move between a position of closed state (FIG. 4A) and a retracted position of the fully open state (FIG. 4B) in a direction orthogonal to the flow path. The end portion of the valve housing 76 is closed by a lid 77. The flow path formed in the valve housing 76 maintains an area equal to or larger than a cross-sectional area of the pipe 52A with the nominal diameter of 200 A, for example.

The gate valve plate (valve) 57 is configured to move straight between an open position at which it retracts out of the flow path and opens, for example, the valve opening 76A, and a close position at which it protrudes into the flow path and contacts the gate valve seat 76C to seal, for example, the valve opening 76A. The gate valve plate 57 is formed to be larger than the valve opening 76A to close the valve opening 76A at the close position.

One or more rods 78 are arranged at the gate valve plate 57 and may move or expand/contract in a moving direction of the gate valve plate 57 together with the gate valve plate 57. In the embodiments of the present disclosure, the rod 78 extends through the lid 77 in parallel with the moving direction. A penetration portion is sealed with a linear motion feedthrough 94 to be described later. Further, the rod 78 may receive a portion or the entirety of a load in the flow path direction applied to the gate valve plate 57 and transmit it to the linear motion feedthrough 94 or the gate valve actuator 80. In that case, the rod 78 has a predetermined strength and a predetermined rigidity (cross-section secondary moment). The driver is not limited to the rod 78, and may be any one that is capable of moving the gate valve plate 57 to open/close the gate valve 56. Therefore, the driver may be, for example, an arm or a ball screw (not shown).

The gate valve actuator 80 is a drive source configured to drive the rod 78 in the moving direction of the gate valve plate 57. The gate valve actuator 80 may be fixed to the lid 77 such that the rod 78 is allowed to be displaced only in the moving direction and withstands loads in other directions (for example, in the flow path direction). As the gate valve actuator 80, for example, a cylinder apparatus, a rack and pinion, or a linear motor is used.

The gate valve seal ring 82 is an O-ring made of, for example, an elastomer, which is arranged on the gate valve seat 76C or a surface of the gate valve plate 57 facing the gate valve seat 76C and is elastic. The gate valve seat 76C is installed on, for example, the upstream side of the gate valve plate 57, that is, on the side of the valve opening 76A. In the shown example, the gate valve seal ring 82 is mounted on the surface of the upstream side of the gate valve plate 57 and moves together with the gate valve plate 57 when the gate valve 56 is opened/closed. For example, the gate valve seal ring 82 is fitted into an annular groove (not shown) formed on the surface of the upstream side of the gate valve plate 57.

In this way, the gate valve 56 may shut off between the valve openings 76A and 76B with a sufficiently low leak amount in a state where there is a pressure difference of 1 atm or more between the valve openings 76A and 76B. A predetermined seal action to press the gate valve plate against the gate valve seat 76C may be performed to cause the gate valve 56 to be in shut-off (seal) state. Further, a permissible pressure difference may be specified as a different value for each of the seal action, an unseal action that releases the pressing, and the drive of the gate valve plate 57 at an arbitrary opening state, as well as the maintained state of being fully closed or shut off. For example, in applications where there is no concern that the pressure will be higher on the downstream side or applications where there is a tolerance for backflow leakage from the downstream side, the gate valve seat 76C may be installed on the downstream side of the gate valve plate 57. In this case, the gate valve seal ring 82 is installed on the gate valve seat 76C or the surface of the gate valve plate 57 facing the gate valve seat 76C, that is, on the surface of the downstream side.

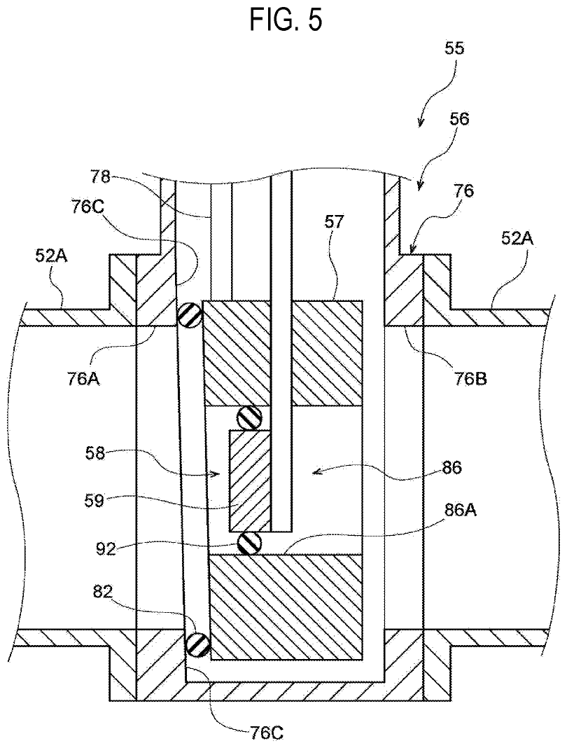

The gate valve 56 is not limited to the one in which the gate valve seat 76C and the surface of the gate valve plate 57 facing the gate valve seat 76C are formed parallel to the moving direction of the gate valve plate 57. As in the example shown in FIG. 5, the gate valve seat 76C and the surface of the gate valve plate 57 facing the gate valve seat 76C may be arranged to be inclined and parallel to each other with respect to the moving direction of the gate valve plate 57. In this case, a wedge effect occurs when the gate valve 56 is closed, thereby improving airtightness between the gate valve plate 57 and the gate valve seat 76C. Further, the downstream side (near the valve opening 76B) of the gate valve plate 57 may be similarly configured. Further, a single-action type gate valve in which the gate valve seat 76C is formed in a unique shape to face the gate valve plate 57 in the moving direction of the gate valve plate 57 may be used. In general, since the gate valve has a structure in which a crushing amount of the seal ring 82 may not be directly controlled, control accuracy of minute opening state (flow rate) is lower than that of other types of valves having the same diameter. Further, due to a large driving force to slide the valve under a large pressure, driving speed is low and responsiveness is poor.

The butterfly valve 58 is an APC valve that is installed at the gate valve plate 57, has a smaller diameter than that of the valve opening 76A opened/closed by the gate valve plate 57, and may be fully closed. The butterfly valve 58 includes a butterfly valve chamber 86, a butterfly valve plate 59, a shaft 88, and a butterfly valve actuator 90.

The butterfly valve chamber 86 is formed to penetrate between both sides of the gate valve plate 57 to allow the two valve openings 76A and 76B to be in fluid communication with each other, and includes a butterfly valve seat 86A. As an example, the butterfly valve chamber 86 is a cylindrical through-hole formed in the gate valve plate 57.

The butterfly valve seat 86A is installed at the inner peripheral surface of the butterfly valve chamber 86. An opening in the butterfly valve seat 86A has an area equal to or smaller than, for example, a flow path cross section of a pipe (not shown) whose nominal diameter is 100 A. A diameter of the pipe of 100 A is about 100 mm (100φ).

The butterfly valve plate 59 is formed in a shape corresponding to the butterfly valve seat 86A and is installed in the butterfly valve chamber 86 with the butterfly valve plate 59 rotatably supported around the movement direction of the gate valve plate 57 as an axis. Specifically, the butterfly valve plate 59 is formed in, for example, a disk shape, and the shaft 88 having an axis passing through a center of the circle is connected to the butterfly valve plate 59. The shaft 88 penetrates the gate valve plate 57 and extends in the moving direction of the gate valve plate 57 to be rotatable around the axis of the shaft 88. Along with the rotation of the shaft 88, the butterfly valve plate 59 also rotates, whereby the butterfly valve 58 opens/closes. Like the rod 78, the shaft 88 of the embodiments of the present disclosure extends through the lid 77.

In the flow path direction of the valve housing 76, the two valve openings 76A and 76B are separated from each other at a distance wider than a size of the butterfly valve plate 59, for example. The size of the butterfly valve plate 59 is a size including a butterfly valve seal ring 92 and is, for example, a diameter. This makes it possible to open the gate valve 56 while maintaining the butterfly valve plate 59 fully open.

The butterfly valve actuator 90 is a drive source that rotationally drives the shaft 88 around the axis of the shaft 88, and employs, for example, a pulse motor or a servomotor to realize an arbitrary opening state of the butterfly valve 58. The butterfly valve actuator 90 of this example is installed by being fixed to the lid 77 outside the valve housing 76.

Further, the butterfly valve 58 includes the butterfly valve seal ring 92. The butterfly valve seal ring 92 is elastic and is arranged on the outer periphery of the butterfly valve plate 59 to abut on the butterfly valve seat 86A, and is, for example, an O-ring. The butterfly valve seat 86A may be sealed by the butterfly valve seal ring 92.

In this way, the butterfly valve 58 may shut off between both sides of the gate valve plate 57 with a sufficiently low leak amount in a state where there is a pressure difference of 1 atm or more. Further, the butterfly valve 58 may be driven freely regardless of the pressure difference, and its operation is faster than that of the gate valve. That is, in general, as the diameter of the butterfly valve increases, sealability becomes worse (the amount of leakage increases), but by selecting the butterfly valve 58 with a diameter sufficiently smaller than that of the gate valve 56, the amount of leakage may be about the same as or less than that of the gate valve 56. Further, since a position of the butterfly valve plate 59 is fixed in the butterfly valve chamber 86 such that the crushing amount of the seal ring 92 is relatively stable, control accuracy at a minute opening state is high. However, the opening state of the control valve 55 obtained by opening only the butterfly valve 58 is about 25% at most.

The gate valve 56 is opened when the opening state of the control valve 55 is relatively large (the conductance or the flow rate of the controlled fluid is large), and the gate valve 56 is closed when the opening state of the control valve 55 is relatively small (the conductance or the flow rate of the controlled fluid is small) or at the time of pressure regulation under predetermined conditions, such that flow rate regulation or pressure regulation is performed by the butterfly valve 58. When the gate valve 56 is fully opened, the main controller 70 controls the butterfly valve plate 59 to an opening state less than a predetermined opening state.

The control valve 55 further includes the linear motion feedthrough 94 and a linear motion rotary feedthrough 96. The linear motion feedthrough 94 makes it possible to connect the rod 78 to the gate valve actuator 80 installed outside the valve housing 76 in a state where an inside and an outside of the valve housing 76 are isolated from each other. The linear motion rotary feedthrough 96 makes it possible to connect the shaft 88 to the butterfly valve actuator 90 installed outside the valve housing 76 in a state where the inside and the outside of the valve housing 76 are isolated from each other. For the linear motion feedthrough 94 and the linear motion rotary feedthrough 96, for example, a well-known bellows, an O-ring seal, or a magnetic fluid seal may be used. The linear motion feedthrough 94 and the linear motion rotary feedthrough 96 may be provided in the form of a piggyback in which one is mounted on the other.

### [Pressure Sensor Group]

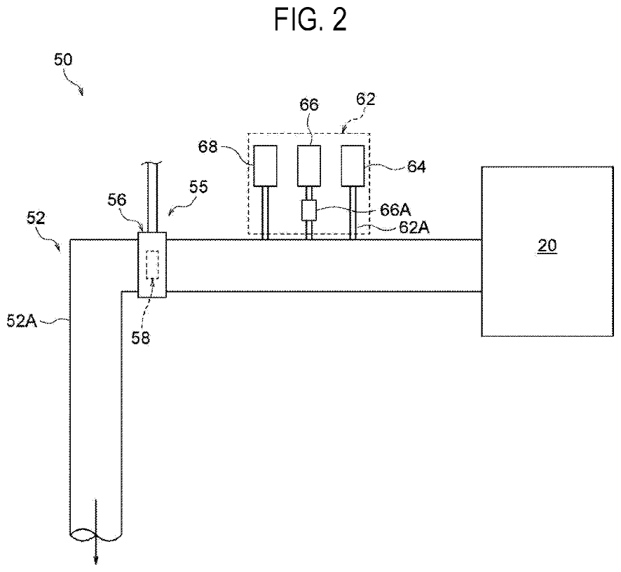

As shown in FIG. 1, the pressure sensor group 62 is installed to be in fluid communication with the process chamber 20 from the installation position of the gate valve 56 by a pipe 62A. The pressure sensor group 62 is electrically connected to the main controller 70 and has a function of transmitting pressure information of the process chamber 20. Further, as shown in FIG. 2, the pressure sensor group 62 includes an atmospheric pressure sensor 64, a first vacuum sensor 66, and a second vacuum sensor 68, which will be described later. The atmospheric pressure sensor 64, the first vacuum sensor 66, and the second vacuum sensor 68 are installed in order from the side closer to the process chamber 20 to the side farther from the process chamber 20, and are connected to the pipe 52A by the pipes 62A, respectively. Here, the atmospheric pressure sensor 64, the first vacuum sensor 66, and the second vacuum sensor 68 are examples of pressure sensors, respectively.

### (Atmospheric Pressure Sensor)

As shown in FIG. 2, the atmospheric pressure sensor 64 is installed at a position closest to the process chamber 20 in the pressure sensor group 62, and has a function of detecting a pressure in a region close to the atmospheric pressure.

### (First Vacuum Sensor)

As shown in FIG. 2, the first vacuum sensor 66 is installed at a position sandwiched between the atmospheric pressure sensor 64 and the second vacuum sensor 68 to be described later, and has a function as a wide area pressure sensor configured to detect a pressure in a region close to the atmospheric pressure to a pressure in a high vacuum region (10⁻¹ to 10⁻⁵ Pa). Further, the pipe 62A connecting the first vacuum sensor 66 and the pipe 52A includes a valve 66A that is opened when an internal pressure of the pipe 52A is reduced toward the pressure in the high vacuum region while being in fluid communication with the atmospheric pressure sensor 64.

### (Second Vacuum Sensor)

As shown in FIG. 2, the second vacuum sensor 68 is installed at a position farthest from the process chamber 20 in the pressure sensor group 62, and has a function as a pressure sensor configured to detect the pressure in the high vacuum region.

All of these atmospheric pressure sensor 64, first vacuum sensor 66, and second vacuum sensor 68 are electrically connected to the main controller 70 and the valve controller 53.

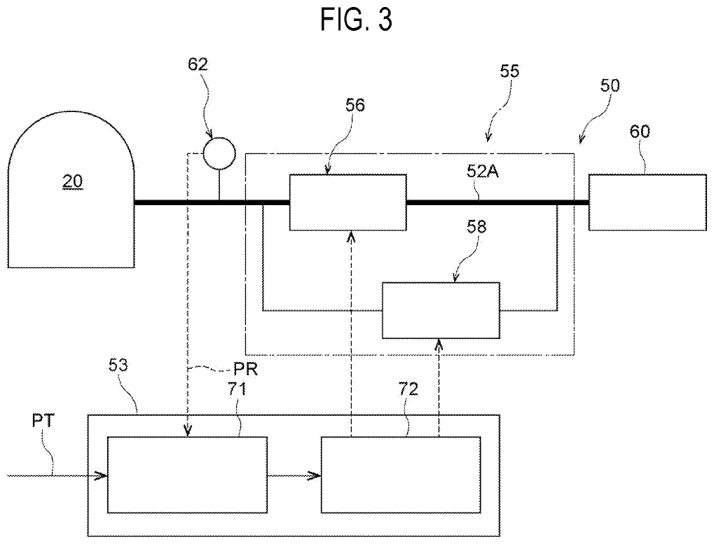

As shown in FIG. 3, in the valve controller 53, an automatic controller 71 receives a target pressure PT of the process chamber 20 given by the main controller 70 and a real pressure PR measured by the pressure sensor group 62 and outputs a target opening state to the opening state command calculator 72. The target opening state corresponds to the conductance of the entire control valve 55 of the embodiments of the present disclosure and is constantly updated by a method such as feedback control so that deviation between the target pressure PT and the real pressure PR becomes zero. In a case where an upper limit of a pressure change rate is specified, even when the target pressure, which changes at a rate exceeding the pressure change rate, is input, the target pressure is internally corrected to converge within the rate. The opening state command calculator 72 allocates opening states to the gate valve 56 and the butterfly valve 58 according to input target opening states and outputs the allocated opening states as opening state commands to the gate valve actuator 80 and the butterfly valve actuator 90 respectively. The opening state command may be given, for example, as a relative opening state when the fully open state of each valve is 100%.

### <Operations of Main Components>

Here, an operation of the control valve 55, an operation of the exhaust system 50, and a method of manufacturing a semiconductor device, which are the main components of the embodiments of the present disclosure, will be described.

### [Operation of Control Valve]

As shown in FIGS. 4A and 4B, in the control valve 55 according to the embodiments of the present disclosure, the rod 78 is moved or expanded/contracted in the axial direction thereof by driving the gate valve actuator 80 according to a command from the valve controller 53, such that the gate valve plate 57 attached to the rod 78 may be moved straight in the axial direction of the rod 78. As a result, the gate valve 56 may be opened/closed. FIG. 4A shows a closed state of the gate valve 56. In the closed state, the gate valve seal ring 82 comes into contact with the gate valve seat 76C to seal the valve opening 76A. FIG. 4B shows the open state, specifically the fully open state, of the gate valve 56. When the gate valve plate 57 is completely retracted from the valve opening 76A, the gate valve 56 is fully opened.

As shown in FIG. 4C, the shaft 88 is rotated by driving the butterfly valve actuator 90 by a command from the main controller 70, such that the butterfly valve plate 59 attached to the shaft 88 may be rotated around the axis of the shaft 88. The butterfly valve seal ring 92 is attached to the butterfly valve plate 59. Therefore, as shown in FIGS. 4A and 4B, when the butterfly valve 58 is in the closed state, the butterfly valve seal ring 92 comes into contact with the entire circumference of the butterfly valve seat 86A installed at the inner circumference of the butterfly valve chamber 86, such that the butterfly valve seat 86A is sealed.

A rotation angle of the butterfly valve plate 59 in the butterfly valve 58 may be controlled by the butterfly valve actuator 90. The fully close position is a position when the butterfly valve plate 59 is perpendicular to the flow of the controlled fluid, and the fully open position is a position when the butterfly valve plate 59 is rotated by 90 degrees from the fully close position to be parallel to the flow of the controlled fluid (FIG. 4C). By changing an angle from the fully open position, the valve conductance may be changed, thereby making it possible to regulate the internal pressure of the process chamber 20 shown in FIGS. 1 to 3. Therefore, according to the control valve 55 of this example, excellent opening/closing operation responsiveness and minute opening state control accuracy may be obtained in a region where only the butterfly valve 58 operates, as in the case of a general small-diameter butterfly valve. Further, sealability comparable to that of a general large-diameter gate valve may be obtained.

The shaft 88 attached to the butterfly valve plate 59 may move or expand/contract at the same time as the rod 78 of the gate valve 56. Therefore, when the gate valve 56 is opened, the butterfly valve plate 59 also moves to the retracted position of the valve housing 76 at the same time as the gate valve plate 57, such that the conductance equivalent to that of the general gate valve corresponding to the pipe 52A of 200 A may be obtained.

Further, by integrating the gate valve 56 corresponding to the pipe 52A of 200 A and the butterfly valve 58 equivalent to 100 A, it is possible to realize large flow rate exhaust and highly accurate pressure regulation at the same time. Further, a branch system (not shown) equivalent to 100 A may not be used, so that the exhaust system may be configured only by the pipe 52A of 200 A. Therefore, it is possible to save a space in a layout of components in an apparatus. Further, since there is no branch pipe, pipe volume may be reduced, such that the replacement efficiency of a gas as the controlled fluid may be improved and component cost may be reduced. Furthermore, in a process where pipe heating is performed, a pipe heating range may be reduced, such that a risk of particles due to non-uniform heating may be reduced.

### [Operation of Exhaust System]

In FIG. 3, when the valve controller 53 appropriately allocates regulation of the opening state of the control valve 55 to the gate valve 56 and the butterfly valve 58 based on the information of the target pressure PT and the real pressure PR from the pressure sensor group 62, the exhaust system 50 of the embodiments of the present disclosure performs pressure control or purging of the process chamber 20.

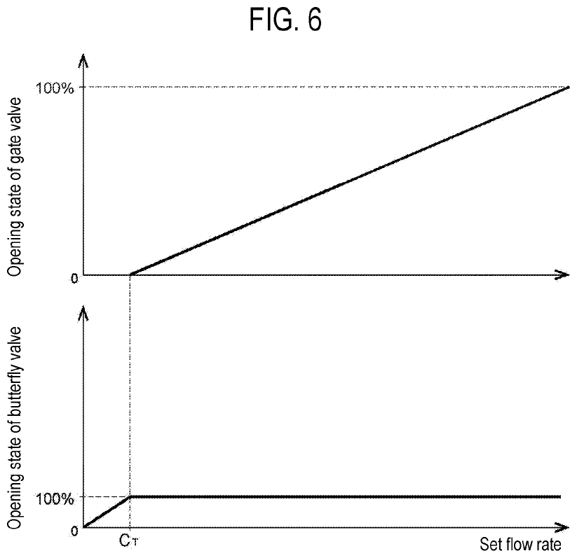

FIG. 6 is a graph showing an example of allocation of opening state by the opening state command calculator 72 (FIG. 3). In this example, a horizontal axis represents a set conductance (or a set flow rate), and a vertical axis represents an opening state of each valve. Specifically, the vertical axis in the upper side of FIG. 6 represents the opening state of the gate valve 56, and the vertical axis in the lower side of FIG. 6 represents the opening state of the butterfly valve 58. In a minute flow rate region of 0 to C_{T} in the horizontal axis, the gate valve 56 is fully closed and only the butterfly valve 58 operates. Here, C_{T} is a transition conductance and corresponds to a conductance of the fully opened butterfly valve 58. When the set conductance exceeds C_{T}, the gate valve 56 operates while the butterfly valve 58 remains fully open. The operation of each valve may be expressed as an opening state that is almost linear with respect to the set conductance. A region where the set conductance is between 0 to C_{T} is a region suitable when controlling the minute flow rate, during which the gate valve plate 57 is pressed against the gate valve seat 76C to seal the gate valve 56 (FIG. 3A). This example may be applied to a configuration in which the gate valve 56 may be fully opened while the butterfly valve 58 is fully opened. The gate valve 56 may be sealed with an arbitrary opening state in which the set conductance is between 0 and C_{T}. Further, when the set flow rate decreases below C_{T}, the sealing of the gate valve 56 is not performed at the same time as the set flow rate falls below C_{T}, but may be performed with a delay after a predetermined time elapses. As a result, frequent sealing operations may be suppressed.

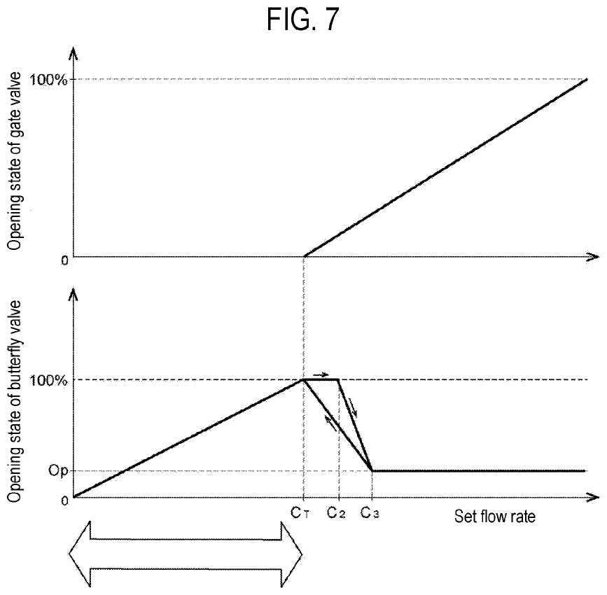

FIG. 7 is a graph showing another example of allocation of opening state by the opening state command calculator 72. This example may also be applied to a configuration in which the gate valve 56 may not be fully opened while the butterfly valve 58 is fully opened. A region on the left side of the transition conductance C_{T} in the horizontal axis, which is indicated by a white arrow, is scaled to be larger than that on the right side of C_{T} of the horizontal axis. C₃ corresponds to the maximum opening state that allows the gate valve 56 to be opened without closing the butterfly valve 58, and at an opening state of C₃ or more, the opening state of the butterfly valve 58 is maintained at Oₚ smaller than its fully open opening state. Here, Oₚ is the maximum opening state of the butterfly valve 58 at which the gate valve 56 may be freely opened/closed without mechanical interference. Between C_{T} and C₃, the opening state command calculator 72 (FIG. 3) performs opening state control having hysteresis. Specifically, when the set opening state increases beyond C_{T}, the opening state of the gate valve 56 is increased while maintaining the opening state of the butterfly valve 58 at 100% until the set opening state reaches C₂. When the set conductance further increases beyond C₂, the opening state of the butterfly valve 58 is controlled to approach Oₚ as it approaches C₃. When the set conductance increases beyond C₃, the opening state of the butterfly valve 58 is maintained at Oₚ, and the opening state of the gate valve 56 is increased. When the set conductance decreases below C₃, the opening state of the butterfly valve 58 is controlled to approach 100% as it approaches C_{T}, and at the same time, the opening state of the gate valve 56 decreases toward 0 almost linearly with respect to the set conductance. According to such control, it is possible to suppress excessive operation of the butterfly valve 58 between C_{T} and C₃, thereby extending life of the butterfly valve seal ring 92 (FIGS. 4A to 4C). Further, when the control valve 55 is rapidly fully closed at the set flow rate from a large flow rate region exceeding C₃, the fully open operation of the butterfly valve 58 speeds up, so that the fully close thereof may be performed at a high speed. When the set flow rate increases from C_{T} to C₃ or more, it is desirable that an interlock is provided for the gate valve 56 such that actual opening state of the gate valve 56 does not to exceed the above-mentioned maximum opening state until the opening state of the butterfly valve 58 drops to Oₚ.

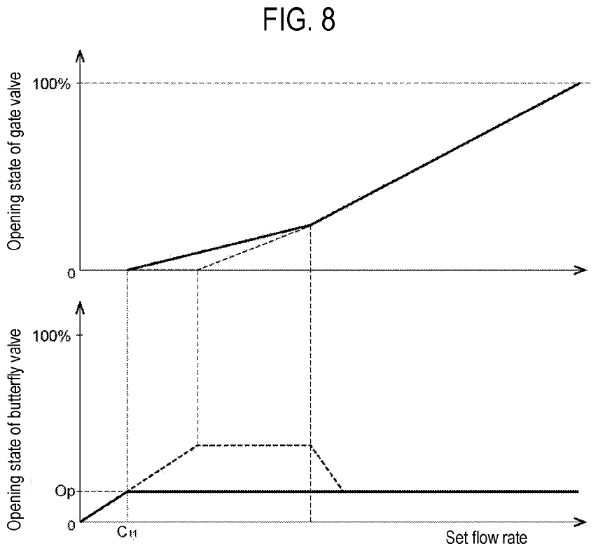

FIG. 8 is a graph showing an example in which the example of FIG. 7 is modified to be more suitable for high-speed opening/closing. In this example, the opening state of the butterfly valve 58 does not exceed Oₚ over the entirety of set conductances. Assuming that the conductance when the opening state of the butterfly valve 58 is Oₚ is Cₜ₁, when the set conductance increases to reach Cₜ₁, the sealing of the gate valve 56 is released, and after that, the gate valve 56 opens with an almost linear opening state with respect to the set flow rate. In this example, although the minute flow rate control region is reduced to deteriorate the accuracy, since actual operations of the gate valve 56 and the butterfly valve 58 may not be awaited, they may be performed completely in parallel. In particular, the opening/closing operation is further accelerated from the fully closed state to the vicinity of Cₜ. When the example of FIG. 7 is called a minute flow rate control preferential mode and the example of FIG. 8 is called a response speed preferential mode, the valve controller 53 may select and apply one of the two modes according to the situations or an instruction of the main controller 70. For example, in a high pressure (that is, low vacuum) region where a differential pressure of the control valve 55 is large, the minute flow rate control preferential mode is selected, and in a low pressure (that is, high vacuum) region, the response speed preferential mode is selected. Alternatively, transition between the two modes may be made continuously according to the pressure of the process chamber 20 in the reaction furnace 10. A control example of the butterfly valve 58 in that case is indicated by a broken line in FIG. 8. The set conductance (predetermined value) at which the gate valve 56 starts to open may be arbitrarily set at least between Cₜ₁ and Cₜ.

### <Substrate Processing Process>

Next, a substrate processing method including a predetermined processing process, that is, a method for manufacturing a semiconductor device, which is carried out by using the substrate processing apparatus 100 according to the embodiments of the present disclosure, will be described. Here, the predetermined processing process is exemplified with a case of carrying out a substrate processing process which is a process of manufacturing a semiconductor device.

The method of manufacturing the semiconductor device includes: a step of providing the control valve 55, which includes the gate valve 56 including the movable gate valve plate 57, and the butterfly valve 58 that is installed at the gate valve plate 57, has a diameter smaller than those of the valve openings 76A and 76B configured to be opened or closed by the gate valve plate 57, and may be fully closed, and configured such that the gate valve plate 57 of the gate valve 56 and the butterfly valve 58 may be driven independently of each other; a step of loading the substrates 30 of the semiconductor device into the process chamber 20 as the reaction chamber of the substrate processing apparatus 100; a step of opening the gate valve 56 when the flow rate of the controlled fluid discharged from the process chamber 20 is large; and a step of closing the gate valve 56 when the flow rate of the controlled fluid is small or at the time of pressure regulation and performing the flow rate regulation or the pressure adjustment by the butterfly valve 58.

In carrying out the substrate processing process, first, the control valve 55 is provided in the substrate processing apparatus 100. Next, a process recipe is deployed on a memory (not shown) or the like, a control instruction is given from the automatic controller 71 to the opening state command calculator 72 in the main controller 70, and an operation instruction is given to a process system controller or transfer system controller (not shown). The substrate processing process carried out in this manner includes at least a loading step, a film-forming step, and an unloading step.

### (Transferring Step)

The main controller 70 instructs a substrate transfer mechanism (not shown) to start a process of transferring the substrates 30 to the boat 26. This process of transferring is performed until the charging of the entirety of the scheduled substrates 30 into the boat 26 (wafer charging) is completed.

### (Loading Step)

When a predetermined number of substrates 30 are charged into the boat 26, the boat 26 is lifted by a boat elevator (not shown) and is loaded into the process chamber 20 formed in the reaction furnace 10 (boat loading). When the boat 26 is completely loaded, the furnace opening lid 28 air-tightly closes the lower end of the furnace opening flange 14 of the reaction furnace 10.

### (Film-Forming Step)

Next, the process chamber 20 is vacuum-exhausted by a vacuum exhauster such as the control valve 55 and the vacuum pump 60 such that a film formation pressure (processing pressure) of the process chamber 20 becomes a predetermined film formation pressure (processing pressure) according to the instructions from the main controller 70 as described above. Further, the process chamber 20 is heated by the heater 18 such that a temperature of the process chamber 20 becomes a predetermined temperature according to an instruction from a temperature controller (not shown). Subsequently, the boat 26 and the substrates 30 are started to rotate by a rotator (not shown). Then, with the process chamber 20 maintained at the predetermined pressure and the predetermined temperature, a predetermined gas (process gas) is supplied to the plurality of substrates 30 held in the boat 26 to perform a predetermined process (for example, a film-forming process) on the substrates 30. Before the next unloading process, the temperature may be lowered from the processing temperature (predetermined temperature).

### (Unloading Step)

When the film-forming step on the substrates 30 mounted on the boat 26 is completed, the rotation of the boat 26 and the substrates 30 by the rotator is stopped, and the process chamber 20 is substituted with a nitrogen atmosphere (nitrogen substituting step) to return the atmospheric pressure. Then, the furnace opening lid 28 is lowered to open the lower end of the furnace opening flange 14, and the boat 26 holding the processed substrates 30 is unloaded to the outside of the reaction furnace 10 (boat unloading).

### (Recovering Step)

Then, the boat 26 holding the processed substrates 30 is cooled extremely effectively by clean air blown from a clean unit. Then, for example, when the boat 26 is cooled to 150 degrees C. or lower, the processed substrates 30 are discharged from the boat 26 (wafer discharging) and transferred to a pod (not shown), and then, new unprocessed substrates 30 are transferred to the boat 26.

### OTHER EMBODIMENTS

Although an example of the embodiments of the present disclosure is described above, the embodiments of the present disclosure is not limited to the above, and may also be variously modified and implemented without departing from the gist of the embodiments of the present disclosure.

According to the present disclosure in some embodiments, it is possible to provide a control valve of good controllability in response to large flow rate exhaust from a reaction chamber.

While certain embodiments are described above, these embodiments are presented by way of example, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A control valve comprising:
a gate valve including a movable gate valve plate; and
a butterfly valve that is installed at the gate valve plate, has a diameter smaller than those of valve openings configured to be opened or closed by the gate valve plate, and is configured to be capable of being fully closed,
wherein the gate valve plate of the gate valve and the butterfly valve are configured to be capable of being driven independently of each other.

2. The control valve of claim 1, wherein a conductance or a flow rate of the control valve is regulated by the butterfly valve such that the gate valve is opened when a set conductance or a set flow rate is larger than a predetermined value, and the gate valve is closed when the set conductance or the set flow rate is smaller than the predetermined value.

3. The control valve of claim 1, wherein the gate valve further includes a valve housing including two of the valve openings arranged facing each other in a flow path direction and a gate valve seat, and linearly forming a flow path of a controlled fluid between the two valve openings, and
wherein the gate valve plate is configured to move between an open position where the gate valve plate retracts out of the flow path and opens the valve openings and a close position where the gate valve plate protrudes into the flow path and contacts the gate valve seat to seal the valve openings.

4. The control valve of claim 3, wherein the gate valve further includes:
a driver arranged on the gate valve plate and configured to be capable of moving in a moving direction of the gate valve plate or expanding or contracting in the moving direction of the gate valve plate together with the gate valve plate;
a gate valve actuator configured to drive the driver in the moving direction of the gate valve plate; and
a gate valve seal ring that is arranged on the gate valve seat or a surface of the gate valve plate facing the gate valve seat and is elastic.

5. The control valve of claim 4, wherein the butterfly valve includes:
a butterfly valve chamber that is provided through the gate valve plate to allow the two valve openings to be in fluid communication with each other and includes a butterfly valve seat;
a butterfly valve plate that is formed in a shape corresponding to the butterfly valve seat and is rotatably supported around the moving direction of the gate valve plate as an axis;
a shaft that is connected to the butterfly valve plate, extends in the moving direction of the gate valve plate, and is configured to be capable of rotating around the axis; and
a butterfly valve actuator configured to drive the shaft to rotate around the axis.

6. The control valve of claim 4, wherein the gate valve seat is installed on an upstream side of the gate valve plate, and
wherein the gate valve seal ring is installed at the gate valve seat or the surface of the gate valve plate facing the gate valve seat.

7. The control valve of claim 5, wherein the butterfly valve is arranged on an outer periphery of the butterfly valve plate, includes an elastic butterfly valve seal ring that abuts on the butterfly valve seat, and is configured to be capable of sealing the butterfly valve seat with the butterfly valve seal ring.

8. The control valve of claim 3, wherein the valve openings are formed in a circular shape, and the valve housing forms the flow path such that a cross section of the flow path is equal to or larger than those of the valve openings.

9. The control valve of claim 5, wherein the two valve openings are separated from each other at a distance wider than a size of the butterfly valve plate in the flow path direction of the valve housing.

10. The control valve of claim 7, further comprising a valve controller configured to control an opening state of the butterfly valve plate to be less than a predetermined opening state when the gate valve is fully opened.

11. The control valve of claim 4, wherein the gate valve seat and the surface of the gate valve plate facing the gate valve seat are inclined with respect to the moving direction of the gate valve plate and are arranged in parallel with each other.

12. The control valve of claim 5, further comprising:
a linear motion feedthrough configured to connect the driver to the gate valve actuator installed outside the valve housing while an inside and an outside of the valve housing are isolated from each other; and
a linear motion rotary feedthrough configured to connect the shaft to the butterfly valve actuator installed outside the valve housing while the inside and the outside of the valve housing are isolated from each other.

13. The control valve of claim 5, wherein areas of the valve openings are equal to or larger than a cross-sectional area of a pipe whose nominal diameter is 200 A,
wherein an area of an opening in the butterfly valve seat is equal to or smaller than a cross-sectional area of a pipe whose nominal diameter is 100 A, and
wherein the control valve is used in a vacuum exhaust flow path from a reaction chamber of a substrate processing apparatus.

14. A substrate processing apparatus comprising:
a process chamber configured to process a substrate;
a sensor configured to detect an internal pressure of the process chamber; and
a control valve that is installed between the process chamber and an exhaust pump and is controlled according to the internal pressure,
wherein the control valve includes:
a gate valve including a movable gate valve plate; and
a butterfly valve that is installed at the gate valve plate, has a diameter smaller than those of valve openings configured to be opened or closed by the gate valve plate, and is configured to be capable of being fully closed,
wherein the gate valve plate of the gate valve and the butterfly valve are configured to be capable of being driven independently of each other.

15. A method of manufacturing a semiconductor device, comprising:
loading a substrate into a reaction chamber of a substrate processing apparatus;
controlling a control valve to exhaust the reaction chamber such that a pressure of the reaction chamber becomes a predetermined pressure, the control valve including a gate valve including a movable gate valve plate and a butterfly valve that is installed at the gate valve plate, has a diameter smaller than those of valve openings opened or closed by the gate valve plate, and is configured to be capable of being fully closed, and the gate valve plate of the gate valve and the butterfly valve being configured to be capable of being driven independently of each other; and
processing the substrate in the reaction chamber.

16. A non-transitory computer-readable recording medium storing a program that causes, by a computer, the substrate processing apparatus to perform a process comprising the method of claim 15.
